(19) United States
(12) Patent Application Publication
(10) Pub. No.: US 2007/0207584 A1
(43) Pub. Date: Sep. 6, 2007

(54) Method and apparatus for curing epoxy-based photoresist using a continuously varying temperature profile

(75) Inventors: Alok Paranjpye, Santa Barbara, CA (US); Douglas L. Thompson, Santa Barbara, CA (US)

Correspondence Address: Jaquelin K. Spong, 2246 Mohegan Drive A1, Falls Church, VA, 22043, US

(73) Assignee: Innovative Micro Technology

(21) Appl. No.: 11/364,334

(22) Filed: Mar. 1, 2006

(51) Int. Cl. H01L 21/8222

(52) U.S. Cl. 438/330

(57) ABSTRACT

A method for curing an epoxy-based photoresist uses a continuously varying temperature profile, to continuously raise the kinetic energy of the monomers involved in the curing process, allowing them to cross-link. By using the continuously varying temperature profile, the maximum temperature to achieve a more completely cured film is reduced, as is the total processing time. In addition, curing using the continuously varying temperature profile is a single step method, rather than a multi-step method of the prior art, significantly simplifying the process flow for producing the cured structures. The cured structures may have mechanical properties which render them suitable as functional elements of various MEMS devices, including rigid, dielectric tethers used in MEMS thermal switches, for example.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to a method for curing epoxy-based photoresist, and a photoresist cured by this method. More particularly, this invention relates to a method and apparatus for curing epoxy-based photoresists more completely, at lower temperatures, and more quickly than the prior art methods.

Microelectromechanical systems (MEMS) are integrated micro devices which may be fabricated using integrated circuit batch processing techniques. MEMS devices have a variety of applications including sensing, controlling and actuating on a micro scale. Accordingly, MEMS devices often include a moveable component such as a sensor or actuator. Often, the sensors or actuators include cantilevered beams which are caused to move by an impulse, such as a current or an acceleration.

For example, MEMS thermal switches are known, wherein one hot beam expands relative to an adjacent cool beam. By coupling the hot beam to the cool beam with a tether, the cool beam is caused to deflect. FIG. 1 shows an example of such a prior art thermal switch, such as that described in U.S. Patent Application Publication 2004/0211178 A1. The thermal switch 10 includes two cantilevers, 100 and 200. Each cantilever 100 and 200 contains a flexor beam 110 and 210, respectively, which pivot about fixed anchor points 155 and 255, respectively. A conductive circuit 120 and 220, is coupled to each flexor beam 110 and 210 by a plurality of dielectric tethers 150 and 250, respectively. When a voltage is applied between terminals 130 and 140 of the conductive circuit 120, a current is driven through conductive circuit 120. The Joule heating generated by the current causes the circuit 120 to expand relative to the unheated flexor beam 110. Since the circuit is coupled to the flexor beam 110 by the dielectric tether 150, the expanding conductive circuit drives the flexor beam in the upward direction 165.

Similarly, applying a voltage between terminals 230 and 240 causes heat to be generated in circuit 220, which drives flexor beam 210 in the direction 265 shown in FIG. 1. Therefore, one beam 100 moves in direction 165 and the other beam 200 moves in direction 265. These movements may be used to open and close a set of contacts located on contact flanges 170 and 270, each in turn located on tip members 160 and 260, respectively. For example, energizing circuit 120, followed by circuit 220, causes the flexing of cantilever 100 in direction 165 and cantilever 200 in direction 265. If circuit 120 relaxes before circuit 220, the switch may be closed by allowing contact 170 to interfere with the return of contact 270 to its original position, and allowing contacts 170 and 270 to close an electrical circuit between flexor beams 110 and 210.

As mentioned above, circuit 120 may be coupled to flexor beam 110 by dielectric tethers 150, and circuit 220 is coupled to flexor beam 210 by dielectric tethers 250. Accordingly, dielectric tethers 150 and 250 must not only have good insulating properties to keep the current from flowing from circuits 120 and 220 into flexor beams 110 and 210, but dielectric tethers 150 and 250 must also have satisfactory mechanical properties, including good stiffness and elasticity. The stiffness transmits the motion of the circuit 120 or 220 to flexor beams 110 and 210, and the elasticity assures that the flexor beam returns approximately to its original position upon cooling of the circuit 120 and 220.

One dielectric material which is particularly convenient to use in such applications is photoresist, because it is easy to pattern into structures 150 and 250 and it is usually insulating. When cured completely, photoresist may also have satisfactory electrical and mechanical characteristics. However, it is necessary to completely cure the photoresist, in order to convert it from its viscoelastic pre-cured condition to its mechanically rigid cured condition.

Prior art methods for complete curing of photoresist, however, require raising the photoresist to just below the point where it starts to decompose. This procedure can lead to some decomposition of the photoresist, and the cracking or delamination of the other films such as flexor beams 110 and 210 and circuits 120 and 220, as well as dielectric beams 150 and 250, from the substrate.

One prior art method for curing epoxy-based photoresist structures 150 and 250 after patterning and development of the structures 150 and 250 is set forth below. This method may be particularly applicable to the epoxy-based photoresist, SU8:

1) Blanket exposing the photoresist;

2) Partially curing the photoresist by heating at 150 degrees centigrade for 60 minutes (total process time, including ramp up and ramp down is 100 minutes);

3) Releasing the photoresist structures from the substrate by removing any sacrificial layers upon which the photoresist is deposited; and

4) Final curing of the photoresist, carried out at 210 degrees centigrade for 30 minutes (total process time, including ramp up and ramp down is 80 minutes).

Ideally, the temperature for step (4) would be even higher, around 240 degrees centigrade, which is the maximum glass transition temperature for epoxy-based SU8 photoresist for a fully cross-linked sample. However, at these temperatures. widespread cracking may occur in the dielectric films and at the interfaces of various films that are part of the devices, which can lead to shorting of the conductive circuits 120 and 220 to the flexor beams 110 and 210, delamination and other problems.

Accordingly, process temperatures of at least 210 centigrade are required in the prior art process for a duration of at least 30 minutes. The prior art process also requires two heating and cooling steps at graduated temperatures. In terms of effectiveness, the prior art process also cures about 80% of the photoresist film. However, because the film is still partially uncured, it continues to possess some viscoelastic properties, rather than the perfectly elastic properties desired.

Accordingly, a method is desired which leads to more complete curing of the photoresist at lower temperatures and for a shorter time, and with a simpler process than the prior art method.

### SUMMARY

The properties of epoxy-based photoresists, such as SU8 developed by IBM Corporation of Armonk, N.Y., are such that as the degree of cross-linking of the material increases, it increases the temperature at which free monomers can shift their position within the material in order to be in a better position to react-with other monomers. Therefore, as the degree of crosslinking in the material increases, the temperature required to continue the crosslinking reaction continually increases. Prior art methods for curing SU8 involved two or more time-steps at successively increasing temperatures, while holding those temperatures for at least about 30 minutes in each time step, in order to achieve an acceptable degree of curing.

The systems and methods described here are an optimized method for curing epoxy-based photoresists such as SU8, and the photoresist cured by this process. The method includes heating the photoresist with a continuously varying temperature profile, wherein the temperature of the film is slowly and continuously increased over time. The curing procedure is applied after he photoresist has been placed and patterned on a wafer, and any underlying sacrificial layers have been removed. By ramping the temperature of the wafer and photoresist, molecules in the film are continually heated to maintain mobility, even as they polymerize the film. This continually keeps the crosslinking reaction progressing, even as the degree of crosslinking increases. After the maximum temperature in the heating phase is reached for a period, the photoresist is cooled, so that the exposure of the photoresist to the maximum temperature is reduced or minimized.

Differential Scanning Calorimetry of the epoxy-based photoresist shows that the material is more completely cured after this process than it is after a multiple discrete time-step curing process. In particular, DSC analysis indicates that the photoresist film is about 86% cured with the continuously varying temperature method as compared to the 82% curing percentage obtained using the discrete step method of the prior art.

One embodiment of the systems and methods provides a ramped temperature gradient which may be about 1.6 degrees centigrade per minute for a total ramp time of about 100 minutes, raising the temperature of the photoresist and substrate from about 40 degrees centigrade to about 200 degrees centigrade. The substrate is then held at 200 C for 30 minutes. Accordingly, the maximum temperature reached by the ramp is only 200 degrees centigrade, well under the maximum glass transition temperature of about 240 degrees centigrade for a fully cross-linked sample of SU8. The total processing time is also shorter, about 160 minutes as compared to about 180 minutes using the prior art procedure.

In another embodiment, the continuously varying temperature function may be non-linear, and have a concave upward or convex downward shape, which may further optimize the process in terms of process time and maximum temperature required.

These and other features and advantages are described in, or are apparent from, the following detailed description.

### BRIEF DESCRIPTION OF THE DRAWINGS

Various exemplary details are described with reference to the following figures, wherein:

FIG. 1 is an illustration of a MEMS thermal switch, which is an application to which the systems and methods disclosed here may be applied;

FIG. 2 is a diagram of a prior art curing process;

FIG. 3 is a diagram of a continuously varying ramp temperature profile curing process;

FIG. 4 is a flow chart showing one exemplary method for forming photoresist structures having good mechanical characteristics;

FIG. 5 is a plot of the output data of a differential scanning calorimeter before curing the photoresist, but after a post-exposure bake step;

FIG. 6 is a plot of the output data of a differential scanning calorimeter after curing the photoresist;

FIG. 7 is a diagram of an exemplary concave continuously varying temperature profile; and

FIG. 8 is a diagram of an exemplary convex continuously varying temperature profile.

### DETAILED DESCRIPTION

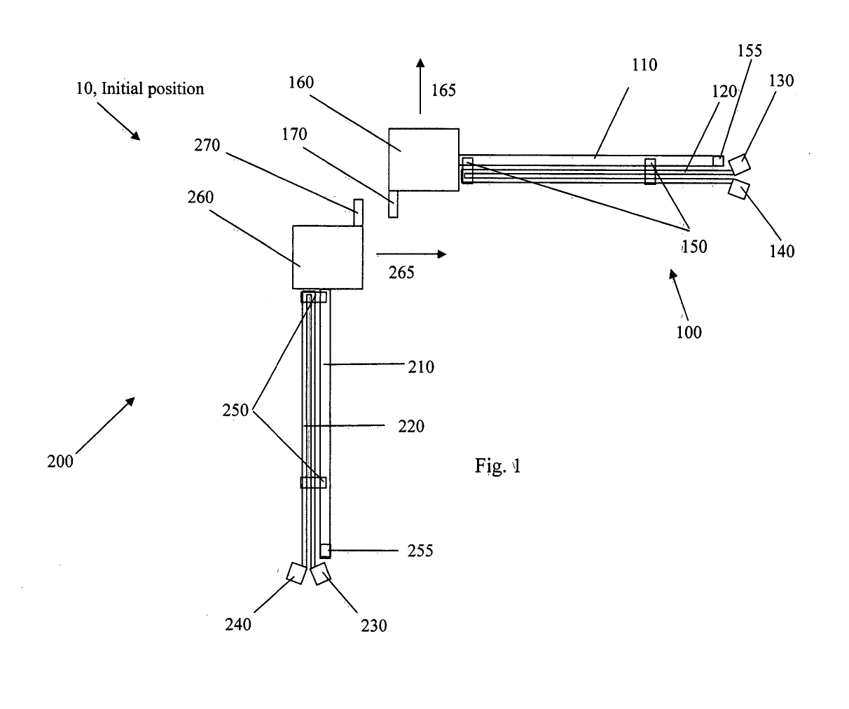

The systems and methods described herein may be particularly applicable to microelectromechanical systems (MEMS) thermal switching devices, such as that depicted in FIG. 1. However, it may also be applicable to any device which requires fully cured, epoxy-based photoresist structures in the device. Such structures may form at least a portion of any of a number of MEMS devices, including a signal processor, a radio frequency filter, an electrical switch, an optical switch, a sensor, a transducer, an accelerometer, and an actuator.

Photoresist, in its cured state, is a crosslinked polymeric material. Commercially available photoresists may consist of the monomers dissolved in a solvent, at varying concentrations. To apply a layer of photoresist to a substrate, a specified quantity of the photoresist solution is poured onto the substrate, which is then rotated at high speed. The rotation throws off any excess material, leaving a uniform, thin layer of the photoresist solution retained on the substrate.

The substrate may now be heated to a predefined temperature to evaporate away the carrier solvent, leaving a layer of photoresist on the surface. Exposing the photoresist layer through a lithographic mask to ultraviolet light, for example, generates photoacids in the photoresist. These photoacids catalyse the crosslinking reaction of the photoresist monomers when the substrate temperature is elevated. This generates areas of linked and unlinked photoresist on the substrate. The regions of linked (or unlinked) photoresist can be dissolved away in a developer to leave a desired pattern of unlinked (or linked) photoresist molecules on the substrate, depending on whether the photoresist is a positive photoresist (or a negative photoresist).

Thus, after patterning and developing the desired structures, it is desired to obtain advantageous mechanical properties from the photoresist regions left behind, and therefore, the photoresist needs to be cured as completely as possible. That is, the monomers in the photoresist need to be encouraged to react among themselves to form a dense network of molecules linked to each other by covalent bonds.

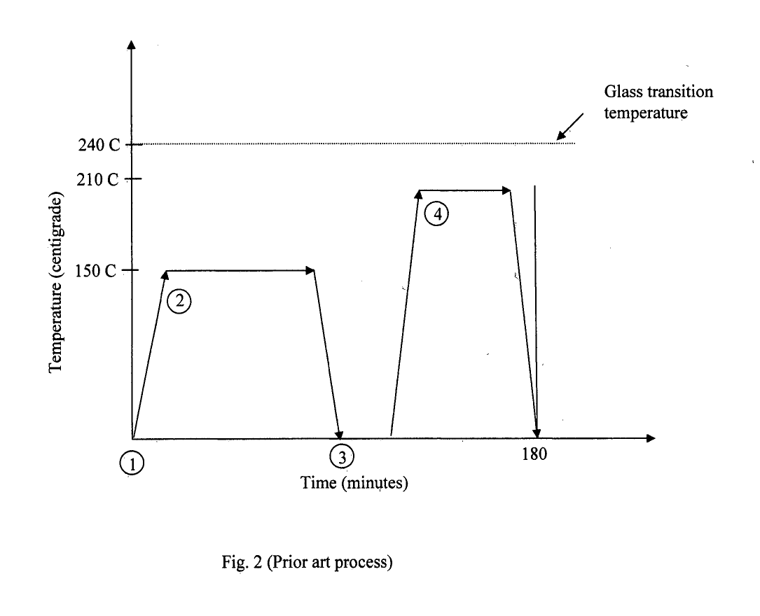

FIG. 2 illustrates the prior art process for curing photoresist. The process depicted in FIG. 2 takes place after the photoresist is patterned and developed. It is intended only to cure the patterned film. The diagram in FIG. 2 corresponds to the process described above, wherein at the point labeled “1”, the photoresist is blanket exposed. The term “blanket exposed,” should be understood to mean that the irradiation source is not positioned behind a lithographic mask, but instead is allowed to illuminate the entire surface of the photoresist and substrate. The blanket exposure step consists of exposing the photoresist to narrow band I-line (365 nm) radiation with an exposure dose of about 3600 mJoules per square cm. The photoresist is then hard baked in two steps, the first step at about 150 degrees centigrade for about 60 minutes. This first step corresponds to the point labeled “2” in FIG. 2. In step “3”, any sacrificial structures underneath the photoresist are removed, prior to the higher temperature step. Removal of the sacrificial material at this point reduces the possibility of cracking of the photoresist because of differences in the coefficients of thermal expansion of the photoresist and the sacrificial layers, especially during the higher temperature second curing step which follows, as shown in FIG. 2. The second, higher temperature step is labeled “4” in FIG. 2. In this step, the photoresist and substrate are heated to a temperature of about 210 degrees centigrade, for about 30 minutes. Each of the heating steps 2 and 4 also have associated cool down phases, so that the entire duration of the curing process (excluding time required for the blanket expose step 1 and the release step 3) is about 180 minutes.

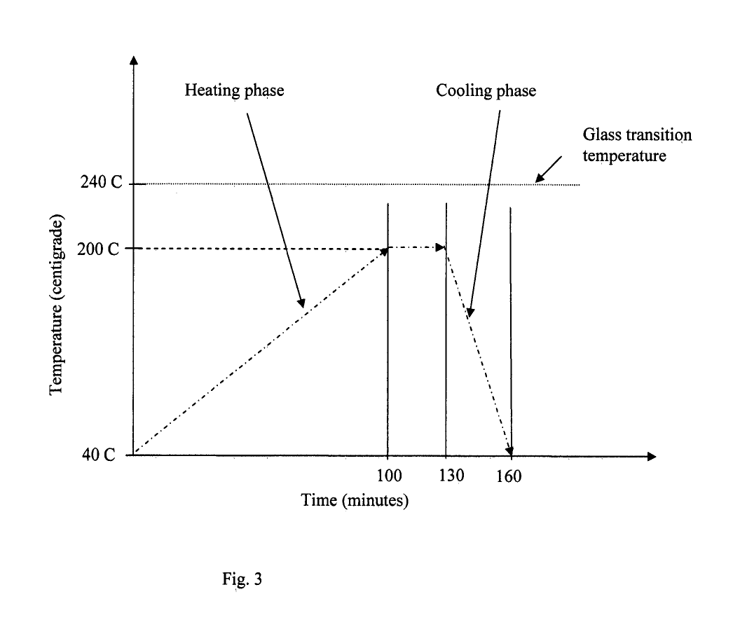

FIG. 3 is a diagram illustrating an exemplary continuously varying temperature profile method for curing epoxy-based photoresist structures 150 and 250. The temperature profile shown in FIG. 3 is substantially continuously varying, by which it should be understood that the temperature varies smoothly as a function of time and does not dwell at any particular temperature longer than about 5 minutes. This profile is in contrast to the step function profiles shown in the prior art procedure of FIG. 2, wherein the temperature dwells at a predefined temperature of about 150 degrees centigrade or 210 degrees centigrade for at least about 30 minutes.

The profile in FIG. 3 shows a linearly increasing temperature profile as a function of time. The slope of the linear ramp profile shown in FIG. 3 may be between about 1 degree centigrade per minute and about 2 degrees centigrade per minute. In one embodiment, this temperature ramp profile is about 1.6 degrees centigrade per minute. In contrast to the multiple-step curing process illustrated in FIG. 2, the ramp method of FIG. 3 is a single-step procedure, that is, the ramp profile shown in FIG. 3 is the only curing step in this process.

In general, the glass transition temperature is coincident with the baking temperature of a sample, that is, as the molecules are heated to a point at which they are free to move, they react with other monomers, becoming cross-linked and thereby increasing the glass transition temperature. For this reason, prior art processes recommended holding the sample temperature at a level near the maximum glass transition temperature, which is about 240 degrees centigrade for a fully cross-linked sample. In contrast, the systems and methods described here gradually raise the temperature of the sample, so that previously immobilized molecules become free to move at the lowest temperature possible. Accordingly, the maximum temperature reached during the continuously varying heating phase, is about 200 degrees centigrade, and is substantially below the maximum glass transition temperature of a fully cross-linked SU8 sample. This provides more complete cross-linking, as described in more detail below, as well as minimizes the exposure time of the sample to high temperatures, which may otherwise damage the films by cracking or decomposition. Furthermore, as shown in FIG. 3, the photoresist is heated only a single time, rather than in multiple, discrete, graduated heating steps shown in the prior art process of FIG. 2.

The photoresist may be held at a maximum temperature for a period of time after which a cooling phase may be applied. For example, the photoresist may be held at the 200 degree centigrade temperature for at least about 15 minutes, and more preferably, about 30 minutes, before the cooling phase is applied. The cooling phase may also be continuously varying, as shown in FIG. 3. The temperature profile of the cooling phase may also be linear, as shown in FIG. 3, or any other shape as long as the temperature is continuously reduced. The cooling phase may be implemented by reducing or eliminating the power to the convection oven, and allowing the sample to cool by heat transfer to the surrounding environment. Therefore, the means for cooling the photoresist may also be the convection oven. Alternatively, the photoresist may be actively cooled in a refrigerator, for example, or simply removed from the convection oven. The total duration of the cooling phase may be about 30 minutes, so that the total duration of the entire curing process using the continuously varying temperature profile of FIG. 3 is about 160 minutes. Because the extra heating and cooling phases of the multistep prior art method are eliminated, the total process time for the continuously varying temperature method shown in FIG. 3 is shorter than the prior art method by about 12.5%.

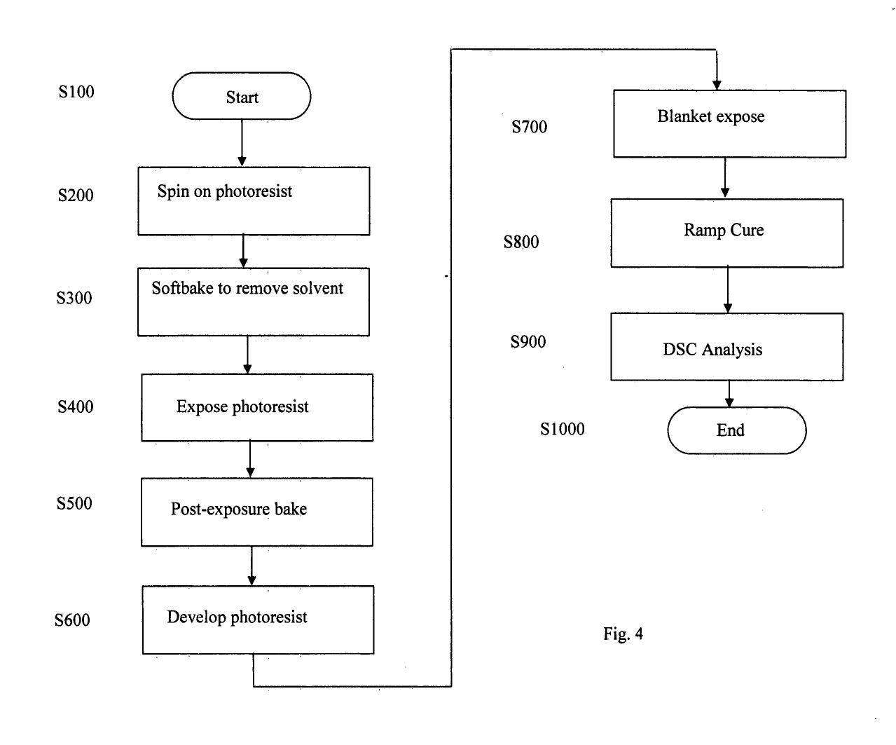

FIG. 4 is a flowchart illustrating a method for creating and curing photoresist structures 150 and 250 for use in, for example, the MEMS thermal switch 10 of FIG. 1. The method depicted in FIG. 4 therefore includes the deposition, exposure and development of the photoresist structures 150 and 250, as well as the curing of these structures.

The method begins in step S100, and proceeds to step S200, wherein photoresist solution is spun onto the surface of the substrate. The photoresist may be, for example, SU8. In step S300, the photoresist is soft baked to evaporate the solvent from the photoresist solution. The evaporation of the solvent may result in a photoresist film in a thickness of, for example, about 13 μm to obtain structures 150 and 250. In step S400, the photoresist is exposed through a mask which may be patterned according to the structures 150 and 250 to be formed on the thermal switch 10. The exposure may generate photoacids which catalyze the cross-linking reaction in the photoresist. In step S500, the photoresist is baked again, to cross-link the exposed portions of the photoresist. This post-exposure bake step S500 may include heating the photoresist to a temperature of about 95 degrees centigrade for about 5 minutes. After the post-exposure bake, the photoresist may be developed in step S600. If the photoresist is a positive photoresist, the exposed portions of the photoresist are dissolved in developer in step S600. If the photoresist is a negative photoresist, the unexposed portions are dissolved in developer in step S600. This step leaves only the desired structures of photoresist, which are then cured as completely as possible. SU8 is a negative photoresist, and the developer solvent for SU8 may be, for example, ethyl lactate or diacetone alcohol. After developing, the photoresist and substrate may be rinsed with acetone to removed any residual organic solvent.

To complete the curing, the remaining photoresist is blanket exposed in step S700, which is by application of broad spectrum illumination, for example, the I-line and G-line radiation from a mercury lamp. Here again, the term “blanket exposure,” should be understood to mean that the radiation is not transmitted through a lithographic mask, but is instead allowed to illuminate the entire surface of the photoresist and substrate. The photoresist is then baked once again to complete its curing in step S800, using, for example, the ramp curing method illustrated in FIG. 3.

After curing the remaining photoresist, the film may be analyzed using a differential scanning calorimeter, or DSC. This step is shown as step S900 in FIG. 4. However, it should be understood that this step may be for diagnostic purposes only, does not need to be performed to produce the fully cured film according to the continuously varying temperature profile shown in FIG. 3.

The differential scanning calorimeter device is known in the art, as a device used for among other things, understanding the curing reactions in thermosetting polymers. To use the differential scanning calorimeter, a small polymer sample in a hermetically sealed pan may be taken through a closely controlled, programmable temperature sequence, during which the heat output or input required to take the sample through the temperature sequence is measured. A typical temperature ramp for the differential scanning calorimeter may be, for example, from 0 degrees centigrade to about 300 degrees centigrade at a rate of about 5 degrees centigrade per minute. Exothermic or endothermic reactions in the sample appear as peaks and valleys in the energy input measurement as a function of temperature, respectively.

The differential scanning calorimeter therefore may monitor the heat produced in a sample at a given temperature. Since SU8 curing is known to be an exothermic reaction, the amount of heat produced may be indicative of the relative amount of incompletely cured photoresist in the film. Therefore, the lower the total energy output during the temperature sequence, the more stable or completely cured the SU8 sample is likely to be.

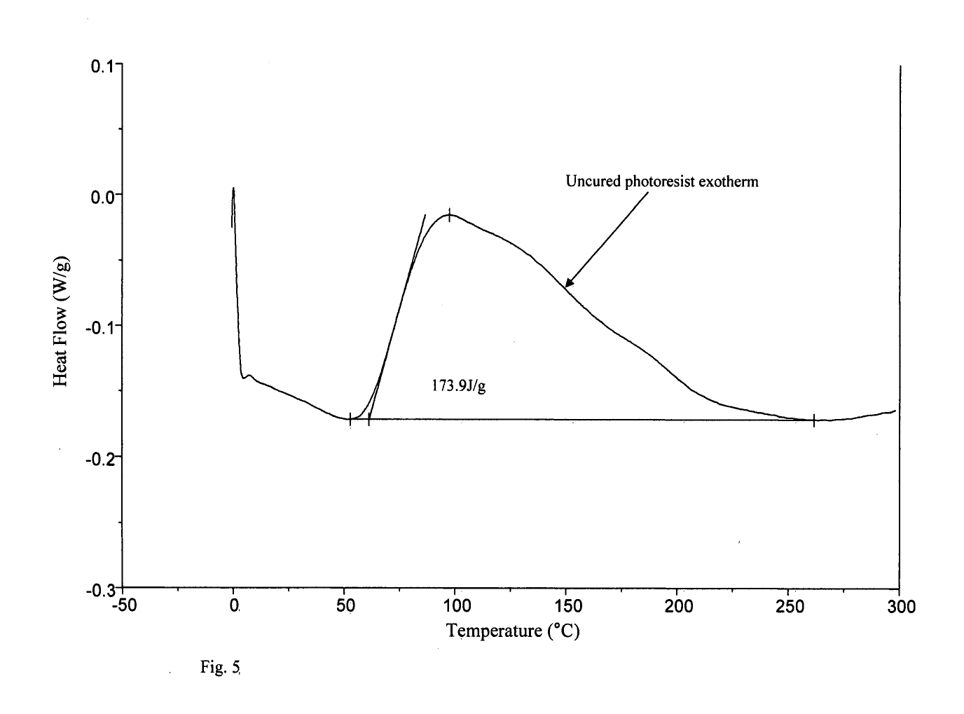

FIG. 5 shows a typical output scan of a differential scanning calorimeter of a film sample after post-exposure bake, but before the film sample has been cured. Therefore, this film sample is taken after step S500 of FIG. 4. Since the photoresist has not yet been cured, a large amount of heat is generated in the photoresist film sample after a temperature of about 75 degrees centigrade has been reached. The integrated area under the curve corresponds to an energy output of about 174 Joules/gram of film sample material. This amount may represent the amount of uncured photoresist left in the photoresist film sample after the post-exposure baking step S500 of FIG. 4.

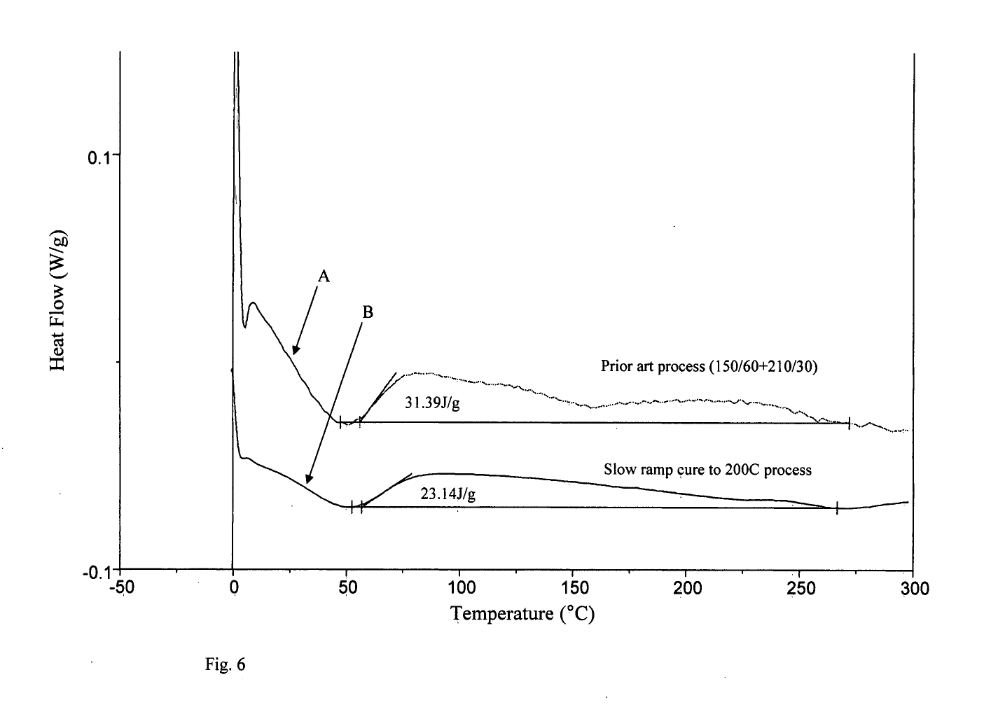

FIG. 6 shows a first differential scanning calorimeter output scan, scan A, of a sample which has been cured by the prior art process illustrated in FIG. 2. According to FIG. 6, the amount of uncured photoresist has been reduced dramatically by the curing process, such that the amount of heat generated throughout the scan is only 31 Joules/gram. Accordingly, one can deduce that about (174−31)/174=82% of the photoresist has been cured by the prior art curing process of FIG. 2.

FIG. 6 also shows a differential scanning calorimeter output scan, scan B, which has been cured by the ramp curing method illustrated in FIG. 3. As shown in scan B, the ramp method results in a more fully cured film, as illustrated by the amount of heat generated in the film being reduced to a level of about 23 Joules/gram. Accordingly, one can deduce that about (174−23)/174=86% of the photoresist has been cured by the ramp method, which is a 4% improvement over the prior art method. Therefore, a characteristic of the epoxy-based photoresist cured by the continuously varying temperature method may be that is has a composition of at least 85% cross-linked polymer, and less than about 15% of uncross-linked monomer. As a result, the photoresist cured by the continuously varying temperature profile may have superior mechanical characteristics compare to the photoresist cured by the prior art method.

In addition to more complete curing of the photoresist, the ramp curing method has several additional advantages over the prior art method. The maximum temperature to which the sample is exposed is somewhat reduced, from 210 degrees centigrade to only about 200 degrees centigrade. This temperature, 200 degrees centigrade, is substantially below the maximum glass transition temperature of a fully cross-linked sample, about 240 degrees centigrade. By reducing the maximum temperature to which the films are exposed, problems with cracking and delamination of the films nay be reduced. A slow ramp up and ramp down of the temperature also reduces damage to the substrate from the thermal shock that may be caused if the temperature is raised more quickly. Therefore, the devices cured using the continuously varying temperature profile may have a higher yield than devices produced using the prior art method, and a lower scrap rate.

In addition, the processing time is shortened, from about 180 minutes total for the prior art method to about 160 minutes total for the continuously varying temperature profile method. This may increase production speed and efficiency by reducing the process time required to produce the photoresist structures 150 and 250, for example.

Finally, the single step curing of the continuously varying temperature profile method significantly simplifies the process flow used to make the structures 150 and 250, as compared to the multi-step process of the prior art shown in FIG. 2. For example, the wafer may only need to be mounted in the heating device a single time, rather than multiple times, reducing the number of opportunities for handling damage to occur.

Another feature of the systems and methods described here is the use of broad spectrum illumination for the blanket expose step S700 in FIG. 4. In the prior art process, to blanket expose the photoresist, narrow band I-line (365 nm) illumination is applied to the film, with an exposure dose of 3600 mJoules per square centimeter. In contrast, the systems and methods described here use broad spectrum illumination, including at least two substantially different wavelengths of radiation, such as I-line and G-line (436 nm) from a mercury lamp. An exposure dosage of about 3600 mJ/cm² may be sufficient for the blanket expose step. By “substantially different,” it should be understood that the broad spectrum illumination applied to the photoresist includes at least one wavelength outside of the characteristic linewidth of one line of the output spectrum of the lamp. Since the photoresist film is relatively thick and transparent to G-line radiation, much of the G-line radiation is passed through the film to greater depths, while the I-line radiation is absorbed at shallower depths. By using both wavelengths, the overall cross-linking of the photoresist is improved throughout the film, yielding a more consistent and uniform structure. Accordingly, the means for blanket exposing the photoresist to broad spectrum illumination may be a mercury lamp applying I-line and G-line radiation to the photoresist sample.

Another aspect of the systems and methods, is the use of a convection oven, rather than -a localized heater such as a hot plate, for example, to heat the photoresist and substrate. A convection oven provides more uniform heating of the photoresist and substrate, such that the temperature profile throughout the film is more consistent and uniform. If a hot plate, for example, is used instead, it is likely that the portions of the photoresist in closer proximity to the hot plate will be heated to a hotter temperature than portions of the film further away from the hot plate. Therefore, the portions of the photoresist closer to the hot plate may begin to decompose, whereas the portions further away from the hot plate may not be fully cured. Thus, the use of a convection oven may also improve the uniformity and consistency of the resulting photoresist structures 150 and 250. Accordingly, the means for heating the photoresist to a maximum temperature with a continuously varying temperature profile may be a convection oven.

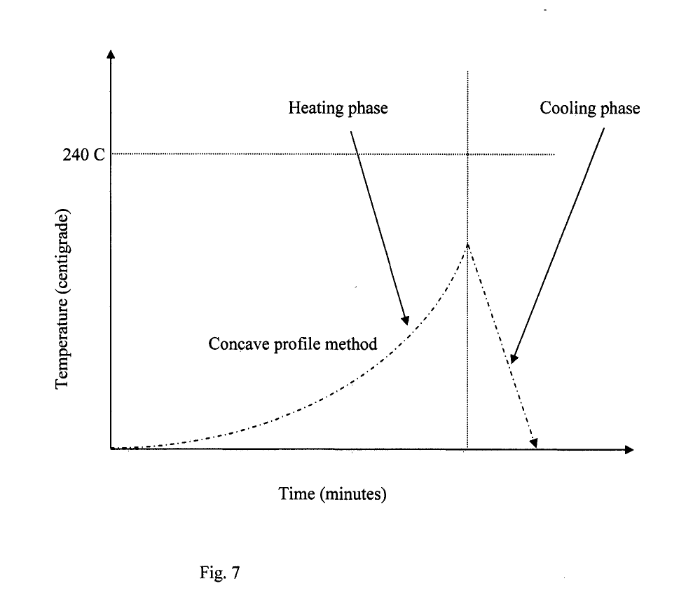

A number of alternative embodiments of the linear ramp profile shown in FIG. 3 may be envisioned. For example, FIG. 7 shows another profile having a temperature which is also continuously varying, but the shape of the profile is concave rather than linear. The function describing the concave shape may be any smoothly varying function, for example, a quadratic or higher order polynomial function or an exponential function. This embodiment may have the advantage that a relatively short amount of time is spent at the higher temperatures, which may reduce any tendency of the photoresist film to decompose. Since at the beginning of the curing process. a larger proportion of the film may remain as monomers to be cross-linked at lower temperatures, increasing the relative amount of time the photoresist is at a low temperature may allow this portion of the photoresist to become cross-linked, without increasing the temperature of the photoresist before it is necessary, to cross-link the remainder of the photoresist material.

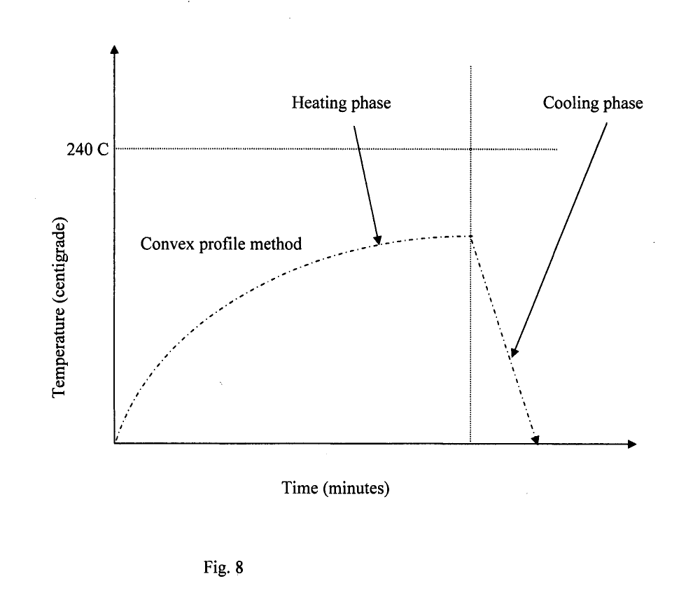

Also shown in FIG. 8 is another exemplary embodiment, wherein the temperature profile is convex. In contrast to the embodiment shown in FIG. 7, this embodiment spends a larger proportion of time at the higher temperatures. This embodiment may be preferable for relatively thick films, in order to give the entire film the opportunity to equilibrate and cure at the higher temperatures. Such a profile may also be useful when the glass transition temperature of the photoresist does not increase linearly with the degree of curing.

Using the continuously varying temperature profiles of FIG. 7 or 8, after a maximum temperature is reached, the photoresist may be immediately cooled as shown, or the maximum temperature may be maintained for some period of time as was shown in FIG. 3.

It should be understood that the cooling phase of the methods shown in FIGS. 3, 7 and 8 may also be convex or concave, rather than the linear ramp shape illustrated in FIGS. 3, 7 and 8. In fact, virtually any continuously varying temperature profile may be used for the cooling phase with the heating phases shown in FIGS. 3, 7 and 8.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. For example, not all of the steps of the method shown in FIG. 4 may be required to practice the curing method using a continuous temperature profile. For example, the differential scanning calorimeter analysis may not be necessary except as a diagnostic tool to monitor the completeness of the curing process. Furthermore, the curing procedure may also be applied to an unpatterned film, such that steps S400-S600 of the method illustrated in FIG. 4 may not be required. Similarly, the embodiment is described with respect to SU8. However, it should be understood that the systems and methods may be applied to any epoxy-based photoresist. Accordingly, the exemplary implementations set forth above, are intended to be illustrative, not limiting.

1. A method for curing an epoxy-based photoresist, comprising:
exposing the photoresist to illumination;
heating the photoresist a single time with a substantially continuously varying temperature profile to achieve a maximum temperature; and
cooling the photoresist after the maximum temperature is reached.

2. The method of claim 1, wherein the maximum temperature is substantially below a maximum glass transition temperature of the epoxy-based photoresist.

3. The method of claim 1, wherein the broad spectrum illumination includes I-line radiation and G-line radiation from a mercury lamp.

4. The method of claim 1, wherein heating the photoresist further comprises heating the photoresist in a convection oven.

5. The method of claim 1, wherein the continuously varying temperature profile is at least one of a linear ramp profile, a concave temperature profile, a convex temperature profile, an exponential temperature profile and a polynomial temperature profile.

6. The method of claim 5, wherein the linear ramp profile has a slope of between about 1 degree centigrade per minute and 2 degrees centigrade per minute, and the linear ramp profile reaches a maximum temperature of about 200 degrees centigrade

7. The method of claim 1, wherein the substantially continuously varying temperature profile of the heating step varies the temperature smoothly as a function of time, without dwelling at a temperature for more than about five minutes.

8. The method of claim 1, wherein cooling the photoresist further comprises cooling the photoresist with a substantially continuously varying temperature profile.

9. The method of claim 8, wherein the continuously varying temperature profile of the cooling step has a duration of less than about 30 minutes.

10. The method of claim 8, wherein the substantially continuously varying temperature profile of the cooling step varies the temperature smoothly as a function of time, without dwelling at a temperature for more than about five minutes.

11. The method of claim 1, further comprising:
maintaining the maximum temperature for at least about 15 minutes, before cooling the photoresist.

12. The method of claim 1, wherein the continuously varying temperature profile of the heating step has a duration of less than about 100 minutes, and reaches a maximum temperature of about 200 degrees centigrade.

13. An epoxy-based photoresist structure cured by a continuously varying temperature profile, comprising:
at least about 85% cross-linked polymer composition; and
less than about 15% uncross-linked monomer composition.

14. The epoxy-based photoresist structure of claim 13, wherein the epoxy-based photoresist structure forms at least a portion of at least one of a signal processor, a radio frequency filter, an electrical switch, an optical switch, a sensor, a transducer, an accelerometer, an actuator and a micromanipulator.

15. The epoxy-based photoresist structure of claim 13, wherein the epoxy-based photoresist structure comprises SU8 with a thickness of about 13 μm.

16. A MEMS thermal switch, comprising:
at least one flexor beam coupled to at least one conductive circuit by at least one epoxy-based photoresist structure of claim 13.

17. The MEMS thermal switch of claim 16, wherein the at least one conductive circuit is heated by a current, and expands relative to the at least one flexor beam to which it is coupled by the epoxy-based photoresist structure.

18. The MEMS thermal switch of claim 17, further comprising at least one current source for driving the current through at least one conductive circuit, thereby heating the conductive circuit and deflecting the flexor beam to which the conductive circuit is coupled by the epoxy-based photoresist structure.

19. The MEMS thermal switch of claim 16, wherein the at least one flexor beam comprises two flexor beams, each flexor beam including a contact pad for making electrical contact between the two flexor beams.

20. An apparatus for curing an epoxy-based photoresist, comprising:
means for exposing the photoresist to illumination;
means for heating the photoresist a single time with a substantially continuously varying temperature profile to achieve to a maximum temperature; and
means for cooling the photoresist after the maximum temperature is reached.
